(19) United States
(12) Patent Application Publication
(10) Pub. No.: US 2017/0269138 A1
(43) Pub. Date: Sep. 21, 2017

(54) FIELD ANALYZER

(71) Applicant: Jason Galluppi, Kintnersville, PA (US)

(72) Inventor: Jason Galluppi, Kintnersville, PA (US)

(73) Assignee: Amplifier Research Corporation, Souderton, PA (US)

(21) Appl. No.: 15/614,784

(22) Filed: Jun. 6, 2017

Related U.S. Application Data
(62) Division of application No. 13/476,409, filed on May 21, 2012.

(51) Int. Cl. G01R 29/08

(52) U.S. Cl. CPC G01R 29/0892; G01R 13/029

(57) ABSTRACT

A visual display of the modulation envelope of an amplitude-modulated RF electric field produced by a field analyzer comprising a field sensor for generating sequential digital samples of the field, a field processor connected to the field sensor for generating a web page, and a personal computer for retrieving and displaying the web page. By using a web page and displaying the web page on a personal computer, it is possible to carry out tasks, such as correcting for nonlinearity of a detector in the field sensor, in the personal computer where they can be performed more efficiently. The sequential samples, which represent the amplitude of the field received by the antenna, are held in a buffer memory, and a bit alignment correction circuit, responsive to the buffer memory, detects and corrects misalignment of the data bits in the buffer memory.

### CROSS-REFERENCE TO RELATED APPLICATION

This application is a division of application Ser. No. 13/476,409, filed May 21, 2012 and published as United States Patent Application Publication No. 2013/0307763 on Nov. 21, 2013. The entire disclosure of application Ser. No. 13/476,409 is incorporated by reference.

### FIELD OF THE INVENTION

This invention relates to field analyzers, and particularly to an apparatus for displaying the modulation envelope of an amplitude-modulated RF electric field. The invention has utility in many applications, and particularly in electromagnetic compatibility (EMC) testing, carried out to ensure that the operation of electrical and electronic systems in products such as automobiles is not adversely affected by radio and television transmissions, radar pulses, cellular telephone signals, powerline fields, and the other kinds of electromagnetic fields.

### BACKGROUND OF THE INVENTION

In EMC testing, a device under test is subjected to electromagnetic radiation swept over a range of frequencies and power levels, and observations are made to determine the effects, if any, of the electromagnetic radiation on the operation of the device. To generate the field, an RF signal is usually generated by a synthesizer, amplified, and fed to an antenna adjacent the device under test. The synthesizer can produce a modulated signal. For example the modulation envelope can be such that the field is applied as a series of pulses having an adjustable repetition rate and adjustable duty cycle.

Although the strength of the field at the location of the device under test can be predicted based on the settings of the synthesizer and the frequency responses of the amplifier and the antenna, the prediction for any given location in the field is not always reliable. Accordingly it is common practice to place a device known as a “field probe” in the vicinity of the device under test to take a direct measurement of the electric field strength.

In conventional field measurement equipment thermocouples are used to determine field intensity. In the case of an amplitude-modulated field, the thermocouples provide only a measurement of average amplitude. Estimates of the peak amplitude levels can be calculated from the average amplitude based on knowledge of the modulating waveform in the synthesizer. However, details of the modulation envelope as it exists at the location of the field probe cannot be determined.

There is a need, therefore, for a field analyzer that allows the user to determine the minimum, maximum, and average amplitude of a modulated electric field, and other waveform details such as peak amplitude, rise and decay time, duty cycle, etc., with high accuracy by direct measurement, i.e., measurement independent of information derived from the synthesizer. It would also be desirable to show these directly measured details of the modulating waveform in a visual, oscilloscope-type, display, in which the instantaneous variation of the amplitude of the modulation envelope over time can be observed. There is also a need for a field analyzer that can rapidly and efficiently make corrections for the non-linear response of the detector in the sensor unit.

### SUMMARY OF THE INVENTION

This invention allows a user to view and measure the modulation envelope of an electric field using an oscilloscope-type display and interface. Instead of using a dedicated oscilloscope-type display, the apparatus according to the invention displays the modulation envelope by utilizing an embedded web page stored in the memory of a microcontroller within a field processor unit associated with a field sensor. The web page, which is loaded onto a personal computer through a standard network connection, has the ability to retrieve new data from the field processor and display it graphically without the need to reload other aspects of the web page. The term “personal computer” as used herein includes not only conventional desktop and laptop personal computers but other devices having the capability of displaying web pages and entering information and selections into a web page, including tablet computers, smart phones and similar devices. The personal computer can be located in the immediate vicinity of the field sensor and field processor, or at any remote location.

More particularly, what is described herein is an apparatus for displaying the modulation envelope of an amplitude-modulated RF electric field. The apparatus comprises three principal components, a field sensor unit, a field processing unit, and a personal computer. The field sensor unit comprises an antenna, a detector having an input connected to the antenna and providing an output, and a sampling circuit responsive to the detector and providing, in digital format, sequential samples representing the amplitude of an amplitude-modulated RF electric field received by the antenna. The field processing unit comprises a receiver for receiving the sequential samples, a microcontroller responsive to the receiver, and including a buffer memory for holding the samples, and trigger-responsive means for uploading data packets from the buffer memory to a web page displayed on a personal computer. The personal computer retrieves the data packets, and displays the data packets as an oscilloscope display of the modulation envelope of the RF electric field on a web page.

The sampling circuit can comprise a clock pulse generator and an analog-to-digital converter, responsive to clock pulses from the clock pulse generator and to the output of the detector, for producing a serial stream of data bits in sequential groups, each group of data bits representing a sample of the amplitude of an amplitude-modulated RF electric field received by the antenna.

The field sensor unit can include an electrical-to-optical converter connected to receive an electrical output from the analog-to-digital converter and to produce a modulated optical signal for transmitting, in the form of a beam of light, data corresponding to the data represented by said serial stream of data bits produced by the analog-to-digital converter. In this case, the apparatus can include a fiber-optic cable connected to the electrical-to-optical converter for receiving the beam of light and carrying the beam of light to the field processing unit. The receiver can be an optical receiver, connected to the fiber-optic cable, for receiving the beam of light and generating an electrical signal in the form of a stream of data bits corresponding to the serial stream of data bits produced by the analog-to-digital converter.

The field processing unit can comprise a clock recovery unit for deriving a synchronization clock signal from the stream of data bits. In this case, the microcontroller can be arranged to receive the stream of data bits and the synchronization clock signal.

The field processing unit can include a bit alignment correction circuit, responsive to the buffer memory, for detecting and correcting misalignment of the data bits in the buffer memory.

A particularly desirable feature of the apparatus is the storage of data characterizing nonlinearity of the field sensor, and utilization of the stored data in the personal computer to correct for the nonlinearity, so that the displayed modulation envelope corresponds to the modulation envelope of the RF electric field at the location of the antenna. The non-linearity characterizing data for a given field sensor can be permanently stored in the memory of a field processing unit associated with that particular sensor, and downloaded from the field processing unit's memory to the personal computer when the apparatus is in operation.

Details and further advantages of the invention will be apparent from the following description when read in conjunction with the drawings.

### BRIEF DESCRIPTION OF THE DRAWINGS

FIG. 1 is a schematic diagram showing the principal components of a field sensor used in the field analyzer according to the invention;

FIG. 2 is a schematic diagram showing the complete field analyzer, including the field sensor, a field processor and a personal computer;

FIG. 3 is a schematic diagram showing the principal components of the field processor;

FIG. 4 is a high level flow diagram showing the operation of the embedded firmware running on the microcontroller of the field processor;

FIG. 5 is a high level flow diagram showing the operation of the web page software running on the personal computer;

FIG. 6 is a flow diagram illustrating the main loop of the microcontroller;

FIGS. 7A-7C are the parts of a flow diagram illustrating the control of the laser that supplies operating power to the field sensor by the microcontroller of the field processor;

FIGS. 8A and 8B are the parts of a flow diagram illustrating the operation of a timeout timer in FIG. 7B;

FIG. 9 is a flow diagram illustrating the operation of a remote communication state machine in FIG. 4;

FIG. 10 is a flow diagram of the operation of a direct memory access (DMA) loop in FIG. 4;

FIGS. 11A-11D are the parts of a flow diagram illustrating the operation of the data state machine loop in FIG. 4;

FIG. 12 is a flow diagram illustrating how a serial peripheral interface (SPI) clock input is reenabled, and a counter and sync counter interrupt are disabled;

FIG. 13 is a flow diagram showing the external trigger interrupt routine.

FIG. 14 is a schematic diagram of an EMC test apparatus incorporating the field analyzer according to the invention; and

FIG. 15 is a drawing of a typical web page as displayed on the screen of personal computer utilized in the test apparatus of FIG. 14.

### DETAILED DESCRIPTION OF THE PREFERRED EMBODIMENTS

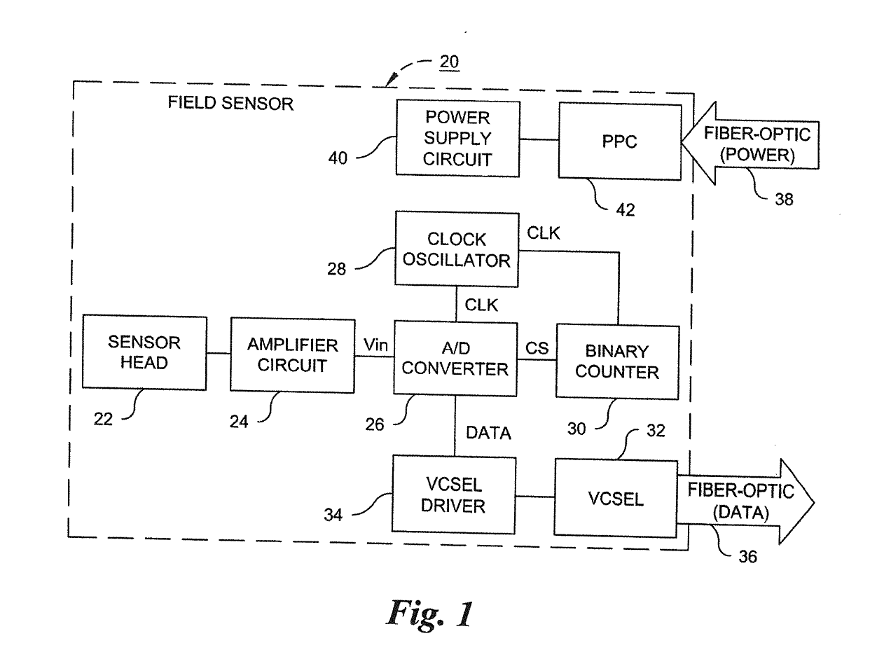

The field sensor 20, which is shown schematically in FIG. 1, can include any of a wide variety of field sensor heads. A suitable field sensor head is described in U.S. Pat. No. 8,305,282, granted on Nov. 6, 2012. The entire disclosure of U.S. Pat. No. 8,305,282 is here incorporated by reference. Briefly, the field sensor head in U.S. Pat. No. 8,305,282 comprises a field sensing antenna composed of a set of three dipoles at the end of a stalk extending upward from a base at an angle of 35.3° from horizontal. The dipoles are arranged so that each dipole extends perpendicular to a plane to which both the other two dipoles are parallel. Thus, by rotation of the stalk, any one of the dipoles can be brought to a vertical condition while the other two are horizontal. The field sensor includes one or more diodes that serve as detectors, producing outputs corresponding to the modulation envelope of the sensed field.

The detector outputs are electrically summed so that the sensor is isotropic, producing a single output. The dipoles, detectors and summing circuitry are represented by the “sensor head” 22 in FIG. 1.

As shown in FIG. 1, the field sensor includes other components in addition to the sensor head. The summed output of the detectors is amplified by amplifier 24, which preferably includes a single pole low pass filter. The filtered and amplified signal is then converted to a digital format by analog-to-digital (A/D) converter 26, the sampling rate being controlled by clock pulses locally generated by clock oscillator 28. A binary counter 30, also responsive to the clock pulses, is used to distinguish the samples. In a typical sampling scheme suitable for this application, the analog to digital converter will take 1.5×10⁶ sixteen bit samples per second, thereby producing a data stream at a rate of 24 Mbits/second.

The digital data are converted to optical data by means of a vertical cavity surface-emitting laser (VCSEL) 32 driven by driver 34, and forwarded through a fiber-optic cable 36. The fiber-optic cable is used because it is electrically non-conductive and therefore does not interfere with the field being measured. For the same reason, power for operation of the electronic components within the field sensor is generated by a laser (not shown in FIG. 1) and delivered through a fiber optic cable 38 to an electronic power supply module 40 through a photovoltaic power converter (PPC) 42. The laser used to supply operating power to the circuitry within the field sensor is a part of the field processor.

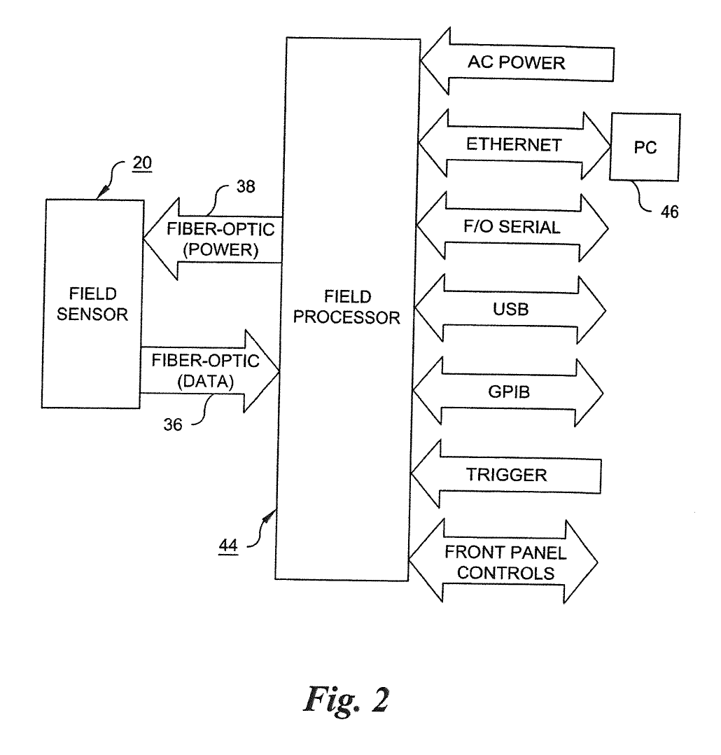

FIG. 2 shows the principal components of the field analyzer hardware. These components include the field sensor 20, a field processor 44, and a personal computer (PC) 46 in communication with the field processor by way of an Ethernet connection. As shown in FIG. 2, the optical data from the field sensor are connected to the field processor 44 through fiber-optic cable 36, and the field processor supplies operating power to the field sensor through fiber optic cable 38. When powered by the laser in the field processor, the field sensor will produce an output in the form of a continuous bit stream until the laser is shut down. It is important to note that the laser used to supply power to the field sensor is necessarily a relatively high-powered laser, and is capable of emitting a hazardous beam if operated while the fiberoptic cable that connects it to the field sensor becomes broken or is disconnected.

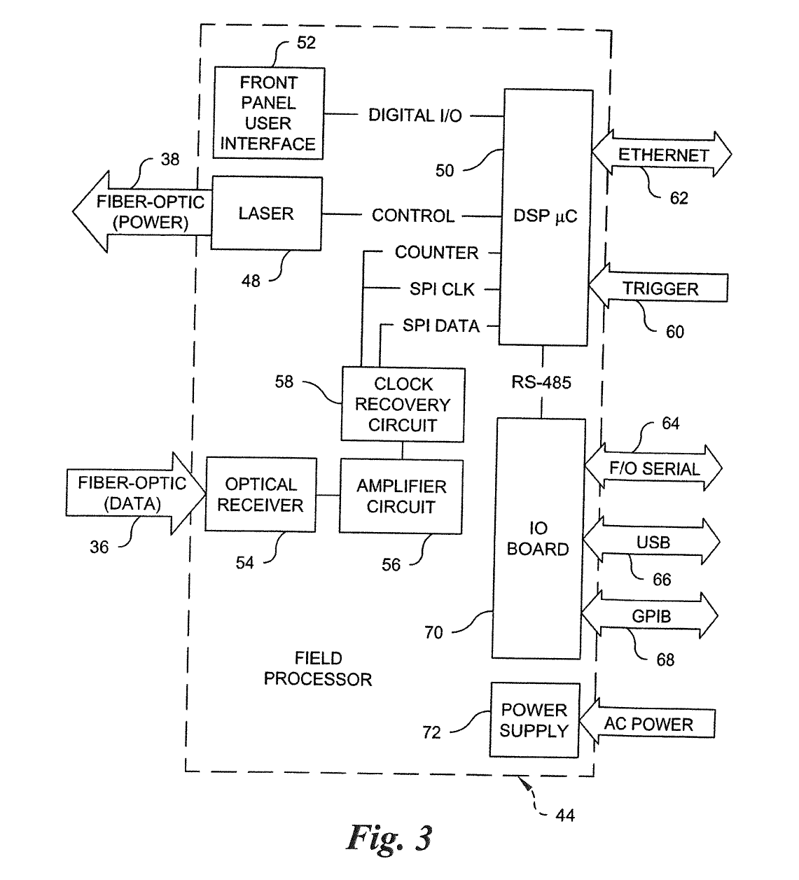

Further details of the field processor 44 are shown in FIG. 3. The laser that provides operating power to the field sensor is an infrared laser 48 under the control of a digital signal processing microcontroller 50, having a user interface 52. Data carried from the field sensor to the field processor through fiber optic cable 36 are converted back to electronic pulses by an optical receiver 54, and the electronic pulses are amplified by amplifier 56. A clock recovery circuit 58 derives a synchronization clock signal from the stream of data bits, reproducing the clock pulses generated by clock oscillator 28 while obviating the separate transmission of clock data from the field sensor to the field processor. The data bits and the clock pulses are separately fed to the microcontroller 50 through a serial peripheral interface (SPI) bus.

The microcontroller 50 utilizes embedded software to manipulate the data from the attached field sensor. The microcontroller uses a Direct Memory Access (DMA) module (not shown) to buffer the digital bit stream into a dedicated holding buffer memory automatically.

An asynchronous (interrupt driven) state machine handles the analyzing and parsing of the field sensor data. This state machine first analyzes the data that has automatically been moved into memory using the DMA module.

Since the bit stream from the field sensor is continuous, the data bits may not be aligned properly when they are automatically transferred into memory by the DMA. That is, the bit positions may be shifted in such a way that the least significant bit of each sample is not stored in the least significant bit position of each memory location. Therefore, the data must be analyzed to determine whether or not the data need to be shifted to correct the bit alignment. In the process of analyzing the data in the buffer memory, the state machine takes advantage of the fact that each sample will have two leading zero bits and two trailing zero bits to determine by how many bits the data need to be shifted. In this process, an amount of data corresponding to the size of the buffer memory is necessarily discarded. However, after data alignment is achieved, it is unlikely that the data will become misaligned again while the apparatus continues to operate.

After the bit alignment is corrected, the state machine tests for a trigger occurrence. A trigger can come from any of three different sources. In a free run mode, a trigger is automatically set each time this part of the state machine is reached. In an internal trigger mode each data sample is analyzed to determine if a user-defined threshold has been crossed. In an external trigger mode, a rising edge on the external trigger port 60 will cause a trigger.

The software can be set to buffer a portion of the data pre-trigger and a portion post-trigger, in order to control the location of the waveform in the display. For example, if 50% of data is pre-trigger and 50% of data is post-trigger, the waveform will be displayed with the trigger occurring at the center of the plot window. If desired, the trigger position can be made user-adjustable.

Once a trigger has occurred, a user-selected time base is used to determine the data packet start and stop points. This information is used to populate a holding buffer using a direct memory access (DMA) module. Once this DMA transfer is complete, the buffer will contain a complete data packet that is ready for upload to the web page. This causes a flag to be set that is polled by the web page allowing it to know that a complete data packet can be retrieved from the field processor. After a trigger occurs, another trigger is not able to occur until the web page has successfully retrieved the previous data packet.

The characteristics of the detector diode or diodes in the field sensor are inherently non-linear and consequently a correction must be made so that the magnitude of the modulation envelope as displayed on the screen of the personal computer accurately represents the magnitude of the field at the location of the field sensor. Moreover, the characteristics can vary from one field sensor to another. To avoid the difficulties that would be encountered in adapting a field analyzer to accommodate each of several different field sensors, preferably the field sensor is associated with a dedicated field processor. Additionally, the characteristic curve of the field sensor's detector is preferably stored digitally in the memory of the field processor as a look-up table and made available for downloading to any personal computer in communication with the field processor through an Ethernet link. When the web page is loaded from the field processor to a personal computer, the stored linearity correction lookup table is also included. This information is then used by the web page to correct the retrieved data packet before the electric field magnitude corresponding to the data packet is displayed in the plot window.

These measures make it easy to use almost any personal computer to display the modulation waveform of the detected field. Using a dedicated field processor for each field sensor and downloading the nonlinearity correcting lookup table to the personal computer with the web page avoid the possible errors that can occur in locating and loading the lookup table for a particular sensor as a separate step. Moreover, making corrections for nonlinearity in the personal computer instead of in the microcontroller reduces the computational burden on the microcontroller. The processor in the personal computer is able to carry out linearization more rapidly than it can be carried out in the field processor.

The web page uses asynchronous JavaScript and XML (AJAX) to compute the minimum, maximum, and average value for the waveform as displayed on the web page. This also contributes to the reduction of the computational burden on the microcontroller.

In addition to data manipulation, the field processor controls laser 48, and also controls remote communications through the Ethernet port 62. Through the Ethernet port, the field processor acts as a web server, providing access to an embedded web page. Other remote communication ports, e.g., a fiber optic (F/O) serial port 64, a Universal Serial Bus (USB) port 66, and a General Purpose Interface Bus (GPIB) 68 following IEEE specification 488, are provided on an Input-Output (IO) board 70 connected to the microcontroller 50 through an RS-485 serial bus.

The remote communication ports on IO board 70 can also be used retrieve data, but not in as much detail as on the web page. All of the controls available on the web page can be remotely set or read using any of the remote communication ports. The minimum, maximum, and average amplitude values can also be obtained through any of the remote communication ports. However, without the web page, linearity corrections must be carried out in the microcontroller, which takes a significantly longer time. The web page also has the advantage that it allows the waveform to be displayed visually.

Power for operating the circuitry in the field processor, and for generating the laser beam that supplies power to the field sensor, is supplied as AC line current to power supply 72 in the field processor, and distributed as direct current at appropriate voltages to the circuitry therein and to the laser 48.

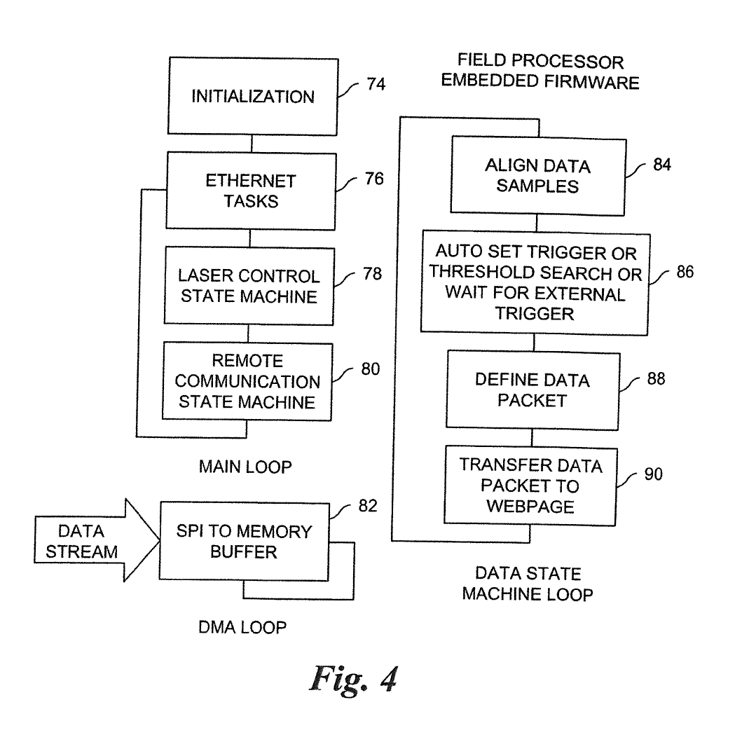

The operations of the software in the field processor and in the personal computer are illustrated in more detail by way of flow diagrams in FIGS. 4-13

FIG. 4 shows the general operation of the embedded firmware of the microcontroller in the field processor unit. Initialization in step 74 initializes all of the variables in the random access memory (RAM) of the microcontroller RAM, and also initializes the peripheral hardware of the microcontroller. The peripheral hardware includes for example the Ethernet physical layer chip, which is a separate chip (not shown) associated with microcontroller 50 (FIG. 3). The clock recovery circuit 58 is also initialized.

Following initialization, Ethernet tasks are implemented in step 76 by a software stack. Here, if an individual, using a personal computer connected to the field processor through the Ethernet port, calls for the web page stored in the microcontroller, the Ethernet tasks load the web page onto the personal computer.

The next block 78 is the laser control state machine. The laser control state machine, as does any state machine, consists of software that proceeds through a sequence, checking states or conditions, and following paths and executing code depending on those conditions. Unless the conditions permit the software of the main loop to proceed to a next stage, the state machine continues to operate in a loop.

The laser control state machine is an important element because the infrared laser 48 (FIG. 3) that supplies operating power to the field sensor delivers a significant amount of power in a concentrated beam. If the fiber optic cable 38 is accidentally disconnected or damaged, for example, the laser control state machine will sense that the clock recovery signal is unavailable, thereby determining that the data stream has either been lost or that it is faulty. In that case, the laser control state machine goes to a state in which the laser is turned off. The laser control state machine also monitors a key-operated switch on front panel of the field processor, ensuring that the key switch is turned on and has not been disabled. The laser control state machine, of course, takes into account the time lag between the turning on of the key switch and obtaining the data stream.

The remote communication state machine (block 80) controls the ports on the IO Board 70 (the F/O serial port 64, the USB port 66, and the GPIB bus 68).

Within the microcontroller, the serial data stream and recovered clock bits on the serial peripheral interface (SPI) are transferred to a memory buffer by direct memory access (DMA) as illustrated by block 82 in FIG. 4. As the buffer memory receives a continuous data stream, the data stream alternately fills one half the buffer memory, and then the other half. While each half of the buffer memory is being filled, the content of the other half of the buffer memory is transferred by direct memory access to a larger buffer memory within the microcontroller. At any given moment what is in the larger buffer memory (or in a part thereof) represents what is seen on the web page.

FIG. 4 also shows the data state machine loop. The first step in this loop is the alignment of data samples in block 84. Since the bit stream from the field sensor is continuous, the data bits may not be aligned properly when they are automatically transferred into memory in the DMA loop. That is, the bit positions may be shifted in such a way that the least significant bit of each sample is not stored in the least significant bit position of each memory location. By looking at the content of the memory buffer and utilizing the fact that each sample will have two leading zero bits and two trailing zero bits, the microcontroller can look for four consecutive zero bits followed by a series of toggling bits, and calculate by how many bits the data need to be shifted. By turning a clock off for a number of bits corresponding to the misalignment, the data can be aligned properly. An amount of data corresponding to the size of the buffer needs to be discarded in this process. However, after the data are aligned it is unlikely that they will become misaligned again.

The next step in the data state machine loop is setting the triggering mode in block 86. The trigger locks a given portion of the buffer content, making it available to the website for viewing. The software can be set to buffer a portion of the data pre-trigger and a portion post-trigger, in order to control the location of the waveform in the display. For example, if 50% of data is pre-trigger and 50% of data is post-trigger, the waveform will be displayed with the trigger occurring at the center of the plot window. If desired, the trigger position can be made user-adjustable.

There are three different modes of triggering. The “auto set” trigger mode is a free running mode, in which, after a portion of the memory content has been transferred to the web page, another trigger occurs automatically so that the web page is continuously updated.

A next mode is an internal trigger mode or “threshold search” mode. In this mode, the microcontroller processor searches to determine whether the data exceeds or falls below a user-set threshold, e.g. 50 v/m. The threshold is computed in the microcontroller using the same stored lookup table that is used in the personal computer to correct for detector nonlinearity. In this mode, the web page remains frozen until the data once again exceeds or falls below the user-set threshold.

In a third mode, referred to as the “external trigger” mode, the modulation waveform is synchronized to an external trigger signal supplied to the microcontroller through trigger port 60 (FIG. 3).

In block 88 of the data state machine loop, the data packet for transfer to the web page is defined selecting both a pre-trigger portion of the data from the buffer memory and a post-trigger portion. In block 90 of the data state machine loop, the selected data packet is then transferred by direct memory access (DMA) to a transfer buffer from which it can be transferred to the web page through the Ethernet port 62 (FIG. 3). The data packet is not overwritten in the transfer buffer. It stays in the transfer buffer until the web page calls for it.

The web page to be displayed on the personal computer in communication with the field processor consists of a set of code stored in the memory of microcontroller and executed by the personal computer. The asynchronous JavaScript and XML (AJAX) allows the fixed parts of the web page to be displayed without being reloaded continually while at the same time allowing the displayed waveform and related data to be updated continually.

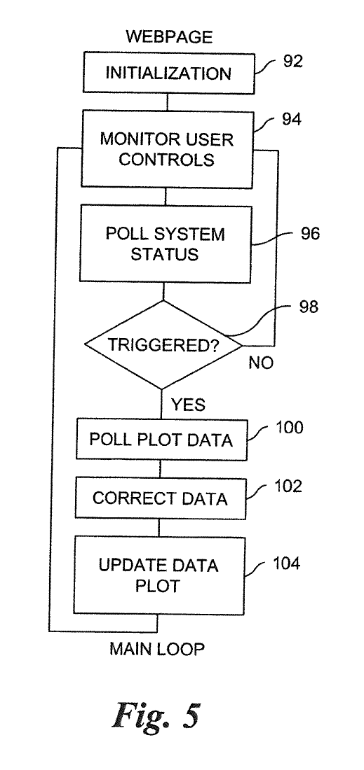

FIG. 5 shows the general operation of the personal computer. Initialization in block 92 sets the memory values in the RAM in the PC. Loading fixed parts of the web page from memory in the microcontroller to the PC is also part of the initialization. In the initialization step 92, the detector linearization lookup table is also loaded from the microcontroller memory to the PC.

If it is available in the memory of the microcontroller, an optional carrier frequency correction table can also be loaded into the PC in the initialization step. The carrier frequency correction table is a look-up table that enables the PC to implement corrections for departures from a flat frequency response in field sensor head 22, amplifier 24 (FIG. 1) and other components of the field sensor.

In step 94, labeled “Monitor User Controls, the user can select various menu options, e.g., time base selection, trigger method, and scaling. If the threshold triggering mode is selected, the user is also able to select a threshold value, and to select whether the trigger takes place on the rising or falling edge of a pulse in the modulation envelope. In step 94, it is also possible for the user to enter corrections to take into account departures of the frequency response of the sensor from a flat frequency response. Entry of a selection in the Monitor User Controls will automatically cause the web page to be reloaded to the PC.

In step, 96, labeled “Poll System Status,” the PC determines whether or not the microcontroller in the field processor has signaled that data is ready, confirms that laser 48 (FIG. 3) is on, and that no faults have occurred. After polling of the system status, an inquiry is made at 98 as to whether or not a trigger has occurred. If a trigger has occurred, the process proceeds to step 100, polling of plot data, i.e. the data which will be displayed on the PC display screen. If there is no trigger, the PC reverts to step 94, and the user can continue to make selections or adjust selections previously made.

Step 102, labeled “Correct Data,” is the step in which the detector nonlinearity correction look up table downloaded to the PC from the memory of the microcontroller is utilized to make corrections in the polled data samples before they are displayed. In this same step, using a separate look-up table, optional corrections can be made for departures of the frequency response of the sensor components and some of the field processor components from a flat frequency response.

In block 104, labeled “Update Data Plot,” the waveform plot and related numerical values are updated on the display of the PC while the remainder of the web page remains unchanged. As each plot is updated, the PC reverts to step 94, and the user can then continue to make selections or adjust selections previously made.

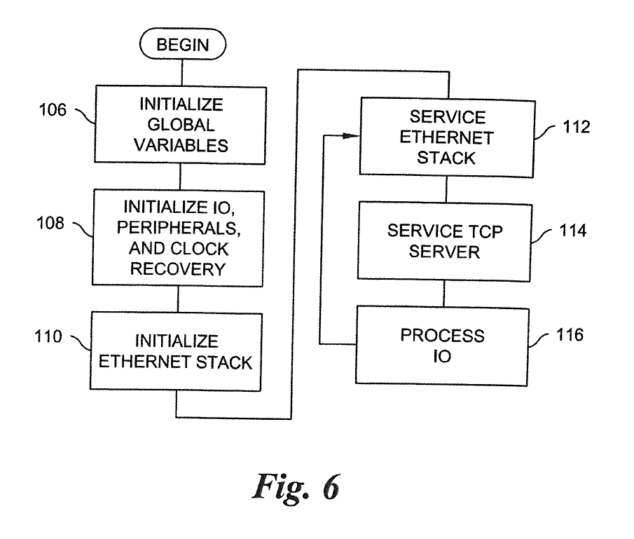

FIG. 6 shows the overall operation of the microcontroller. In step 106, the global variables in the software are initialized. In step 108, the input-output (IO) and peripherals, as well as the clock recovery variables are initialized. In step 110, the Ethernet stack is initialized. Following these initializations, a loop then begins with servicing of the Ethernet tasks at step 112. This is followed by servicing of a TCP (Transmission Control Protocol) server in step 114. Finally, the laser control state machine process is begun in step 116.

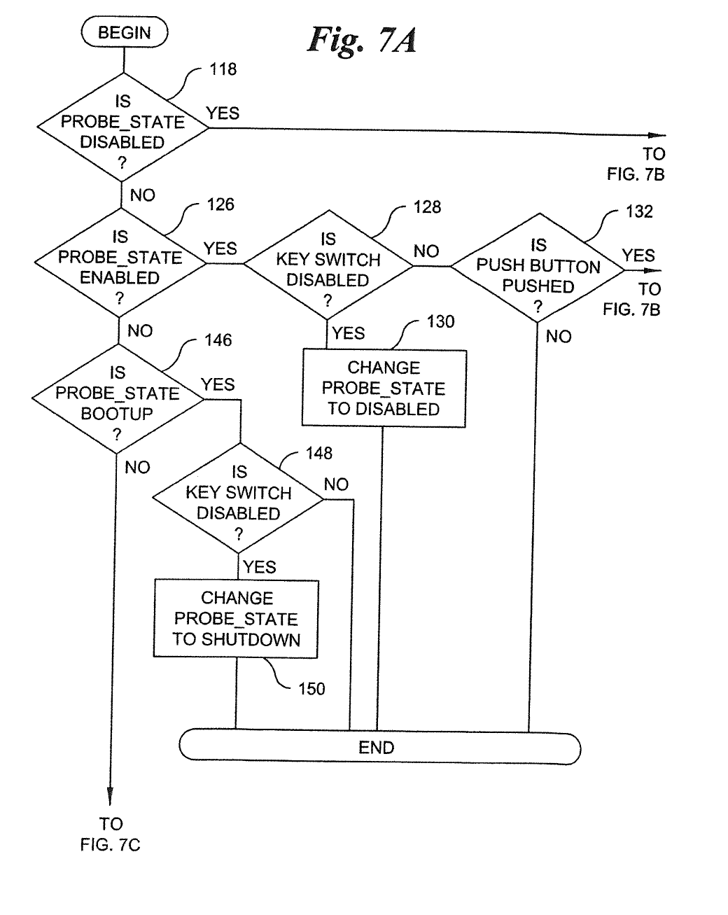

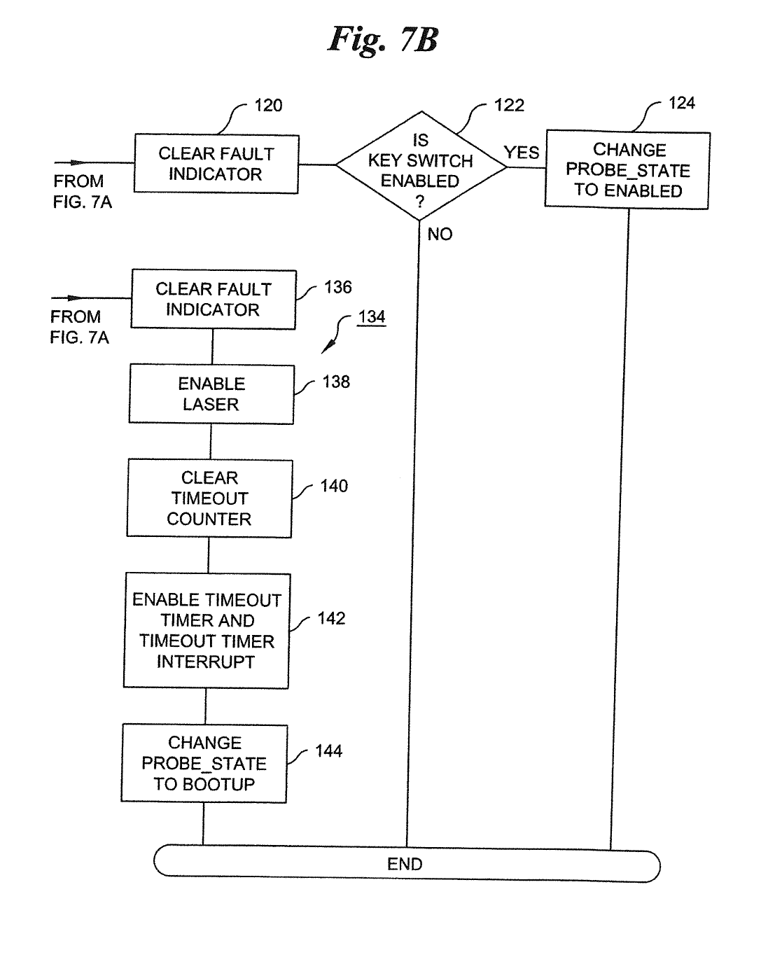

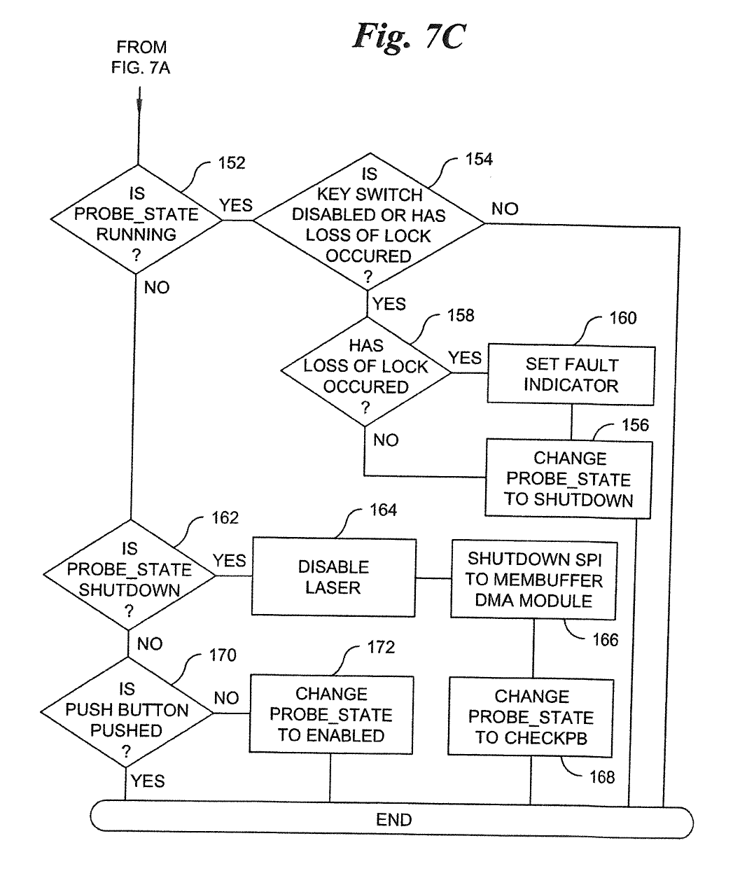

Operations depicted in general in FIGS. 4-6 are explained in more detail below with reference to FIGS. 7A-13.

### Laser Control State Machine

Details of the operation of the laser control state machine (block 78 in FIG. 4) are depicted in FIGS. 7A-7C. The sensor (also referred to as a “probe”) has six states, as follows:
disabled
enabled
bootup (waiting for data)
running (data is coming back)
shutdown
check pushbutton (is pushbutton being held?)

As shown in FIG. 7A, the laser control state machine first determines whether or not the probe is disabled in decision block 118. If the probe is disabled, the process proceeds through a step 120 (FIG. 7B) in which a fault indicator is cleared, and an inquiry is made at block 122 as to whether or not a key-operated switch on the field processor unit is enabled, i.e., the key-operated switch is turned “on”). If the key switch is enabled, the probe is enabled at step 124, and the laser control state machine reaches an “end” stage in which the operation of the main loop in FIG. 4 proceeds to the remote communication state machine 80. Similarly, if the key switch is found not to be enabled, the operation proceeds to the “end” stage without enablement of the probe.

In FIG. 7A, if the probe is not determined to be disabled in block 118, the process proceeds to decision block 126, where an inquiry is made concerning whether or not the probe is enabled. If the probe is enabled, a determination is made in decision block 128 concerning whether or not the key switch is disabled. If the key switch is disabled, the probe state is changed to “disabled” in block 130, the operation of the laser control state machine ends, and the main loop in FIG. 4 proceeds to the remote communication state machine in block 80. On the other hand, if the key switch is determined not to be disabled, then an inquiry is made at decision block 132 concerning whether or not the laser activation pushbutton is pushed. If the button has been pushed, the operation proceeds through a set of steps 134 in FIG. 7B, in which a fault indicator is cleared in step 136, and the laser is enabled at step 138. In step 140, a timeout counter is cleared. The timeout counter, which is enabled in step 142, allows the system to wait for the field sensor to boot up and start sending data. The probe state is changed to bootup at step 144.

Returning to FIG. 7A, if the probe state is determined not to be enabled, an inquiry is made at block 146 concerning whether or not the probe is in the bootup state. If it is, since the probe state is not enabled, the state machine determines at block 148 whether or not the key switch is disabled, i.e., turned off. If the key switch is disabled, the probe state is changed to shutdown at block 150 and the laser control state machine reaches its “end” condition, so that main loop proceeds to the remote communication state machine block 80 in FIG. 4.

If, the decision at block 146 is that the probe is not in the bootup state, the state machine proceeds to FIG. 7C, where an inquiry is made in block 152 concerning whether or not the probe is in the running state, i.e., that it is receiving data. If the probe is running, then the state machine checks both for disabling of the key switch and for loss of lock at block 154. Loss of lock occurs if the clock recovery chip has not indicated an active lock on the data stream. If there is no active lock, the data stream is either not present, or unusable if it is present. If either of these two conditions has occurred, the probe state is shifted to shutdown at block 156 and the laser control state machine goes to its “end” condition. In the meanwhile, the state machine determines at block 158 whether or not the decision made in block 154 was due to a loss of lock. If so, a fault indicator is set at block 160.

If the probe is not in the running state as determined at block 152, an inquiry is made at block 162 as to whether or not the probe is in the shutdown state. If it is, the laser is disabled at block 164, the direct memory access (DMA) module that transfers data from the serial peripheral interface (SPI) to the buffer memory in the microcontroller is shut down at block 166, and the probe state is changed to the “check push button” state in block 168.

If the probe is not in the shutdown state, as determined at block 162, the state machine checks the laser activating push button at block 170. If it is not pushed, then the probe is enabled at block 172. On the other hand, if the push button is pushed, the laser control state machine loops around, checking the push button once again. Checking the pushbutton in this manner prevents the user from holding the pushbutton and thereby forcing the loop to restart, in which case the laser could be operated by holding the pushbutton even if the laser-carrying fiber optic cable is not connected to the field sensor.

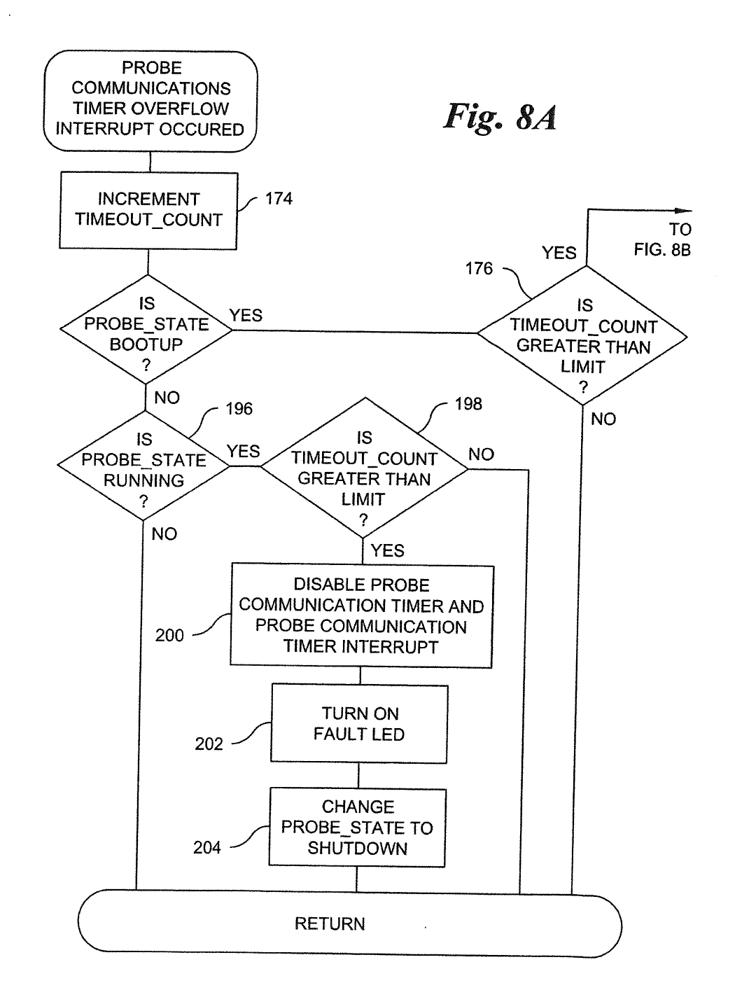

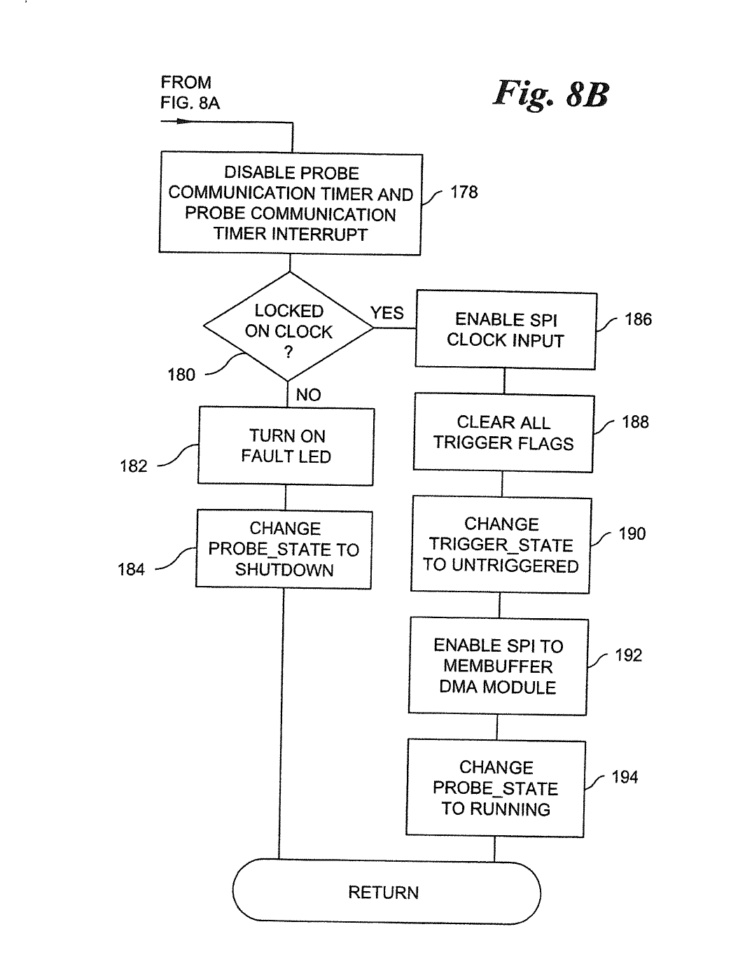

FIGS. 8A and 8B illustrate the enabling of the timeout timer in block 142 of FIG. 7B. In FIG. 8A, if probe communications timer overflow interrupt occurs, the timeout count is incremented at block 174, and the probe state is checked. If the probe is in “bootup”, the timeout count is checked at decision block 176. If the count exceeds a predetermined limit, the timeout timer (is disabled at block 178 (FIG. 8B) and a check is made for loss of lock at decision block 180. In the event of a loss of lock, a fault indicator is activated at block 182 and the probe is shut down at block 184. If the data are locked to the clock, the SPI clock input is enabled at 186, trigger flags are cleared at 188, the state machine is set to “untriggered” at 190, the SPI—to buffer memory DMA module is enabled at 192 and the probe state is changed from “bootup” to “running” at 194.

Returning to FIG. 8A, if the probe is not in the “bootup” state, the state machine determines at 196 whether the probe state is “running.” If it is running, and the count in the timeout counter exceeds a predetermined limit as determined at decision block 198, the probe communication timer is disabled at 200, a fault indicator is activated at 202 and the probe state is changed to “shutdown” at 204. The system thus ensures that a data stream is coming in to the field processor from the field sensor. If the data stream is present, the timeout counter is continually reset. If the count exceeds a predetermined limit while the probe is in “bootup” or “running,” or if a loss of lock is detected, the probe is shut down.

### Remote Communication State Machine

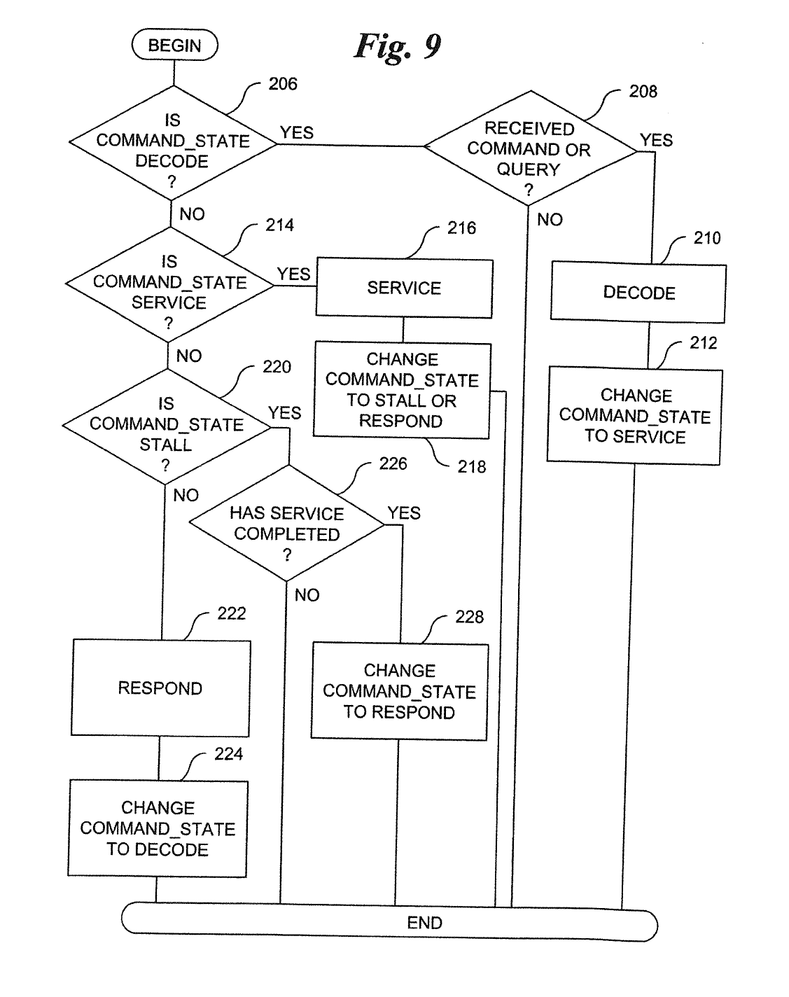

Details of the operation of the remote communication state machine (block 80 in FIG. 4) are depicted in FIG. 9.

The possible states of the remote communication state machine are:
decode interpreting the command or query that came in and determining what the field analyzer has to do to respond
service initialize to carry out the action decoded by the decode subroutine
stall waiting state to allow certain services to complete
respond initiate the response

In block 206, the state machine checks for a “decode” command state. The “decode” state is the default state, i.e., the starting point. In the decode state, the remote communication state machine waits for data to come in through the Ethernet port 62 (FIG. 3) or through one of the ports 64-68 in the IO board 70 (FIG. 3). A determination is made at decision block 208 whether any data (whether or not it is a valid command or query) have come in through one of the ports. If data are present, a decoding subroutine is executed at block 210 to determine what came in through the port, and the state shifts to “service” at block 212. On the other hand, if no data are present, the command state remains at “decode.”

When the command state is not “decode,” the state machine determines at decision block 214 whether or not the state is “service.” If it is, then a service subroutine is executed at 216 and the command state is changed to “stall” or “respond” at block 218, depending on whether or not other operations need to be completed as determined by the code in the “service” subroutine.

At decision block 220, if the state machine is neither in the “decode” state nor the “service” state, a determination is made concerning whether or not the machine is in the “stall” state. If not, the machine responds at block 222 and the command state returns to the default state, “decode,” at block 224.

If the machine is in the “stall” state at block 220, it remains in that state until the service has been completed. If the service has been completed, as determined at block 226, the machine state is shifted to “respond” at block 228.

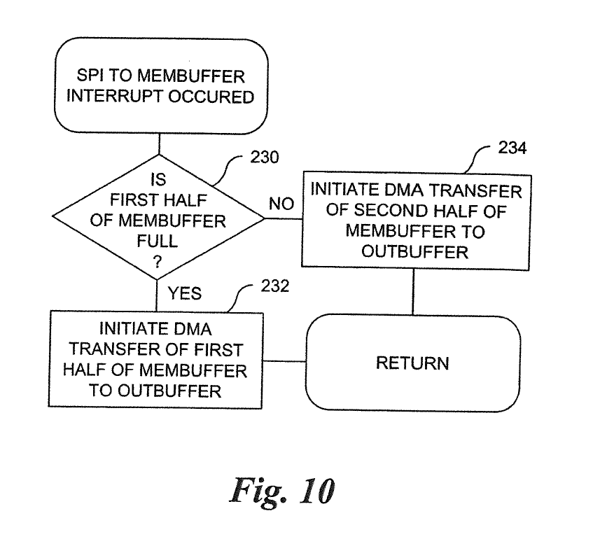

FIG. 10 shows the operation of the DMA loop 82 in FIG. 4. A buffer memory (“membuffer”) in the microcontroller has two halves, the contents of which are alternately transferred to a larger output buffer (“outbuffer”). An interrupt occurs both when the buffer memory is half full, and when it is full. When the interrupt is generated, and the first half of the buffer memory is determined to be full at block 230, transfer of the contents of the first half of the buffer memory to the output buffer by direct memory access (DMA) is initiated at block 232. However, if the first half of the buffer memory is not full at the time of the interrupt, and the second half is full, the contents of the second half of the buffer memory are transferred to the output buffer at block 234.

### Data State Machine Loop

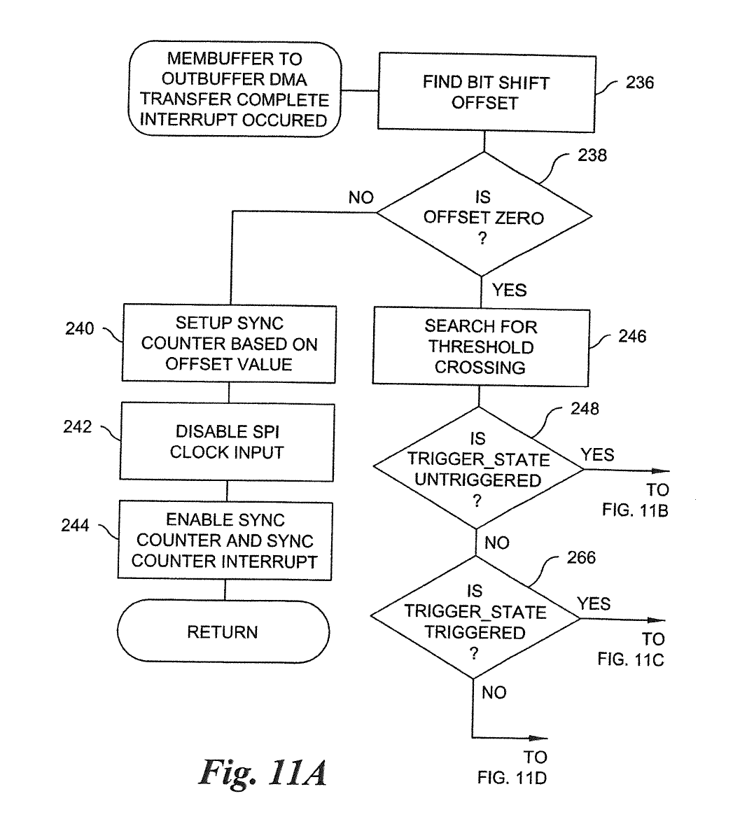

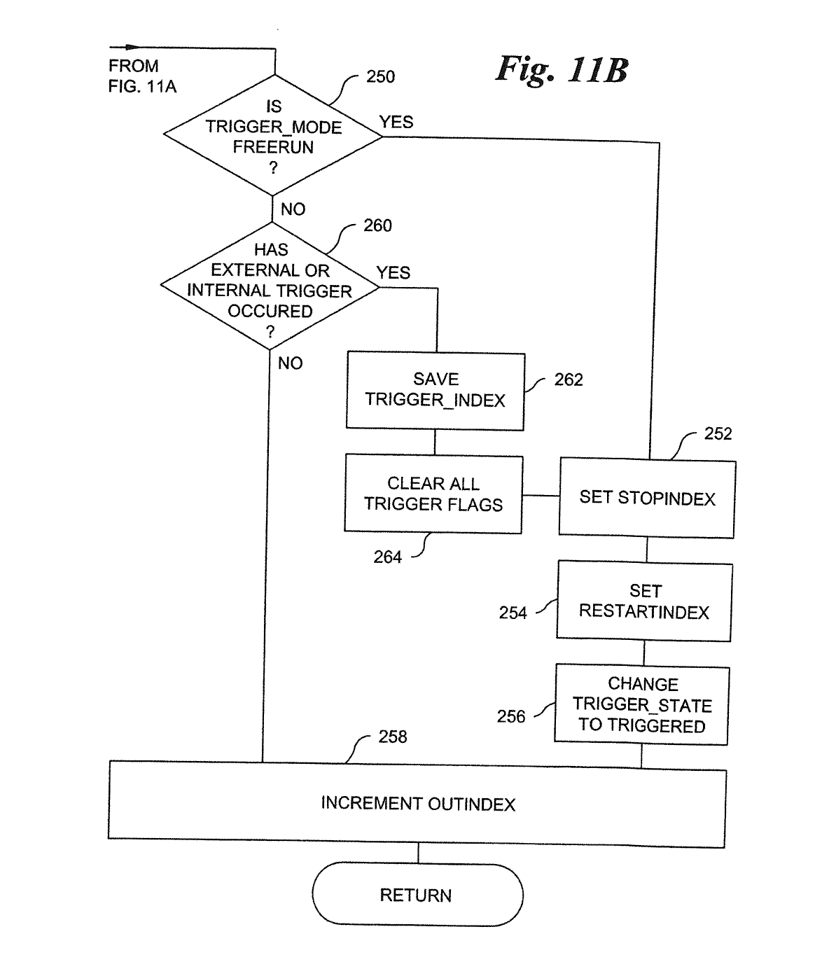

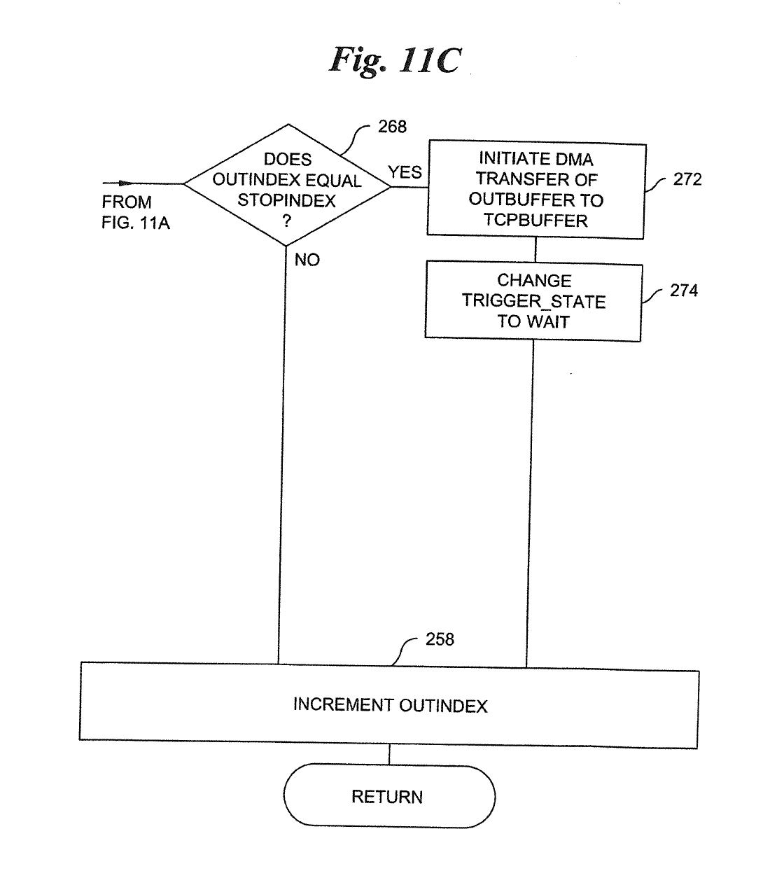

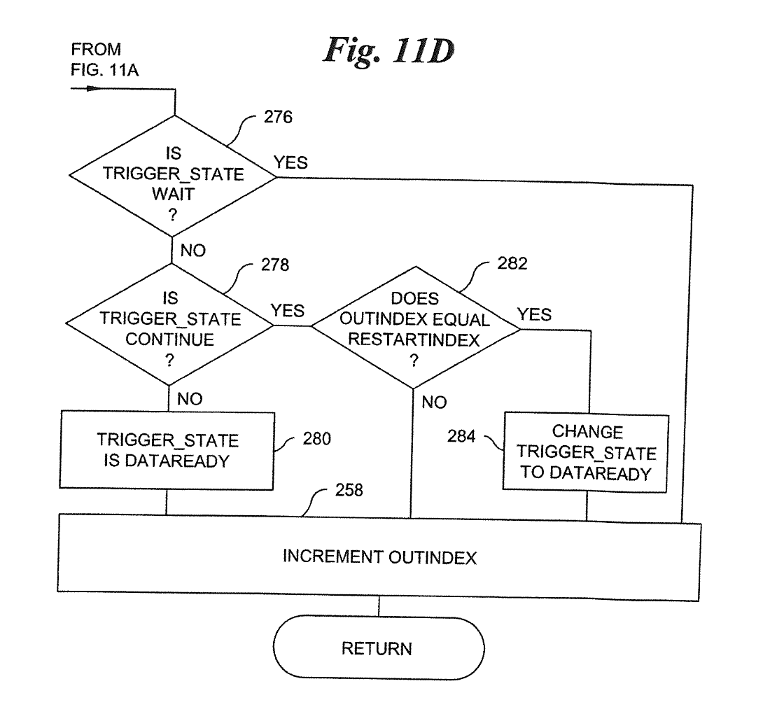

Each time a DMA transfer to the output buffer in FIG. 10 is completed, the data state machine loop in FIG. 4 operates to assemble and transfer data packets to the web page. FIGS. 11A-11D show the operation of the data state machine loop of FIG. 4, particularly blocks 84, 86 and 88.

The states in blocks 84, 86, and 88 of the data state machine are:
untriggered
triggered
wait
continue
data ready

In FIG. 11A, the most recently transferred block of data is analyzed to determine whether or not the bits are aligned with the proper memory locations. The offset, i.e., the extent of the misalignment, is determined, and a correction is made.

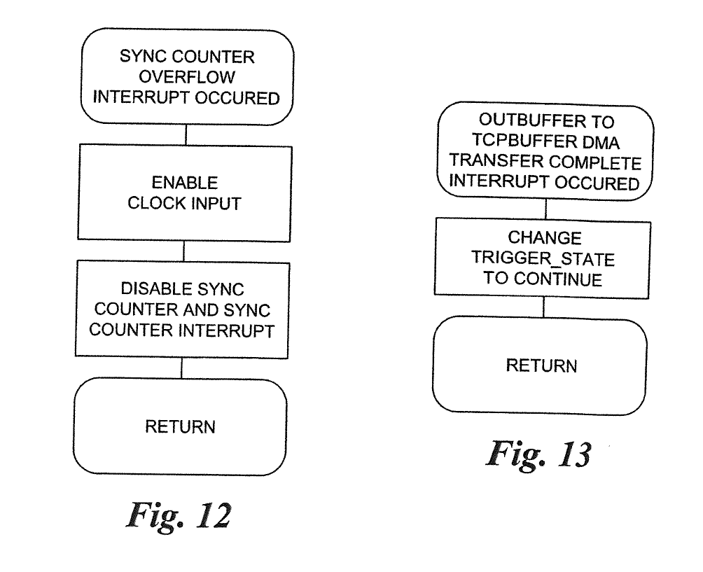

As shown in FIG. 11A, if the data bits are misaligned, the number of bits by which the data are offset is determined at 236. If a misalignment has occurred, as determined at block 238, a sync counter is set at block 240, based on the offset value, and a SPI clock input is disabled at block 242. That is, the SPI clock bits sent by the clock recovery circuit 58 to the microcontroller in FIG. 3 are counted by an internal counter in the microcontroller, but not used to clock data into the buffer memory. The sync counter and the sync counter interrupt are enabled at block 244. Referring to FIG. 12, the offset counts are counted, the SPI clock input is reenabled, and the counter and sync counter interrupt are disabled. With the SPI clock reenabled, data from the SPI bus can again enter the buffer memory.

Returning to FIG. 11A, if the offset is zero, the microcontroller looks for a threshold crossing at block 246, i.e., it searches through the data representing samples in the output buffer for the earliest sample that exceeds (or falls below) a preset threshold. If the threshold is crossed, but the trigger state is “untriggered,” the path proceeds from block 248 to FIG. 11B, where the state machine determines whether the trigger is in the free run mode at decision block 250. If the trigger is in the free run mode, the information that is sent to the web page is determined by setting a stop index at block 252. A restart index is set at block 254 by calculating backward from the stop index, and the restart and stop indices determine the data to be sent to the web page so that the data do not overlap. The trigger state is changed to “triggered” at block 256. Because the output buffer contains multiple packets, it is necessary to increment an index, referred to as the “outindex,” in block 258 to keep track of those packets and avoid overwriting them.

If the trigger is not in the free run mode, the state machine checks at block 260 for an external trigger at port 60 (FIG. 3) or an internal trigger. The internal trigger will have been determined by the threshold search in block 246 (FIG. 11A).

If an external or internal trigger has occurred, a trigger index, determined either by the threshold search, or by an external trigger interrupt routine depicted in FIG. 13, is saved at block 228. Trigger flags used to determine index value are cleared at block 264, and the system proceeds with setting the stop and restart indices as in the case in which the trigger is in the free run mode.

Referring again to FIG. 11A, if the trigger state is determined to be “triggered” at decision block 266, the system proceeds to FIG. 11C, and a determination is made at block 268 as to whether or not the stop index has been reached. If the stop index has not been reached, the outindex is incremented at 258.

If the stop index has been reached, a portion of the output buffer content is determined by working backward from the stop index based on a user-selected time base, and a direct memory access (DMA) transfer is initiated at block 272 to move that selected portion of the output buffer to a transfer control protocol (TCP) buffer, which is a third buffer memory in the microcontroller, the trigger state is changed to “wait” at block 274 and the outindex is incremented. If the transfer is completed, the state changes to “continue” in FIG. 12.

Returning to FIG. 11A, if the trigger state is determined to be neither “triggered” nor “untriggered” in decision blocks 248 and 266, the system proceeds to FIG. 11D, where decision blocks 276 and 278, determine whether the trigger state is “wait,” “continue,” or “data ready.” If the trigger state is neither “wait” nor “continue,” then the trigger state is “data ready” at box 280, and the outindex is incremented. If the trigger state is “continue,” the outindex is compared with the restart index in block 282, and if the outindex and restart index are equal the trigger state is changed to “data ready” at block 284. In either case, the outindex is incremented. The web page checks for the data ready state by polling system status in block 96 in FIG. 5. When the web page takes the data, the trigger state returns to “untriggered.”

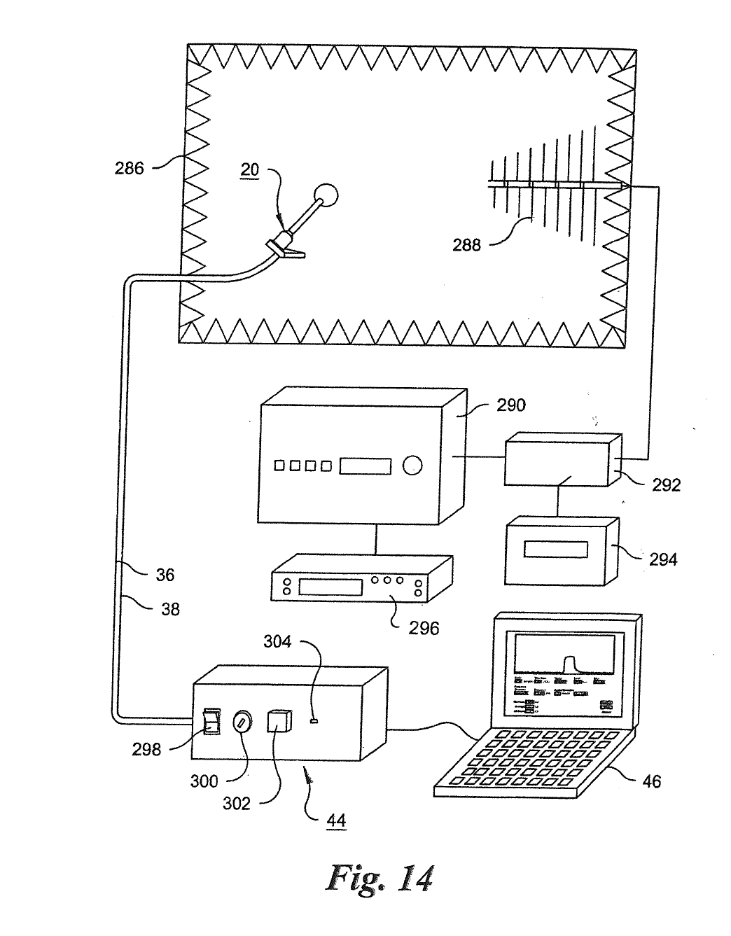

The field analyzer of the invention can be utilized in a test apparatus such as that shown in FIG. 14, in which the field sensor 20 is located in an a test chamber 286 lined with anechoic cones and tiles. An antenna 288, or other suitable device for applying an electromagnetic field to a device under test (not shown) in the chamber is connected to the output of an RF amplifier 290 through a directional coupler 292. Output power is monitored by a power meter 294 connected to the directional coupler. The RF signal is generated by a synthesizer or other suitable signal generator 296 connected to the input of the amplifier.

As shown in FIG. 14, the field sensor 20 is connected through fiber optic cables 36 and 38 to the field processor unit 44, cable 36 carrying the data from the sensor, and cable 38 delivering operating power to the field sensor. The field processor is connected to personal computer 46 through an Ethernet link.

On the front panel of the field processor unit 44 are a power switch 298, a key-operated switch 300, a momentary push button 302 for activating the laser that delivers operating power to the field sensor, and a fault-indicating LED 304.

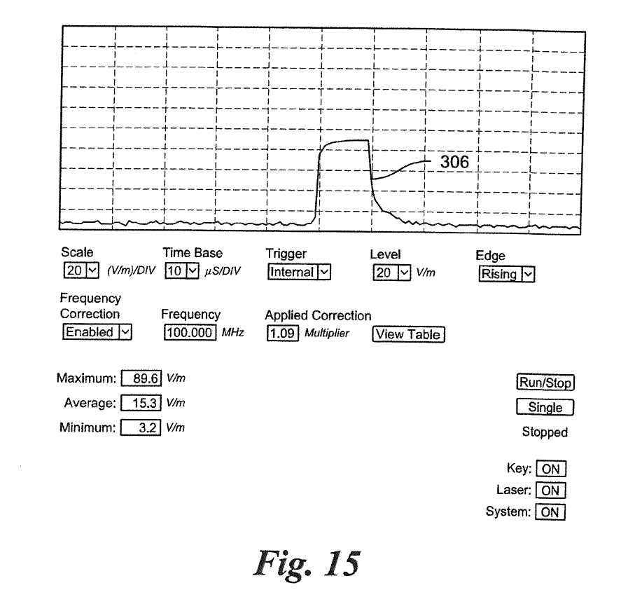

The web page displayed on the personal computer 46 is shown in greater detail in FIG. 15. The display shows the modulation envelope 306 of the RF signal received by the field sensor. Various parameters for the display can be selected by means of a graphical user interface on the web page. For example, the amplitude scale and time base can be selected as can the trigger type (external, internal or free run) trigger level, and trigger edge (rising or falling). Frequency correction, i.e., correction for the deviation of the field sensor's frequency response from a flat response, can be enabled or disabled, and the frequency, as well as the maximum, minimum and average amplitudes of the modulation envelope can be displayed. The amount of the correction is displayed as a multiplier.

A “view table” button is provided on the screen to give the user the ability to view the stored table of frequency correction values that are used by the webpage to derive the applied correction multiplier. A “Run/Stop” button is used to start and stop the update of the waveform display manually. A “Single” button is provided to stop the update of the waveform display automatically after a single trigger event has occurred. Status displays indicating the key switch position, the status of the field sensor power supply laser and the system status are also provide on the web page.

The software details shown in FIGS. 4-13 are examples of a large number of possible ways to implement a field analyzer in which a field sensor generates digital samples of a modulation envelope of an RF field, and a field processor generates a web page for displaying the modulation envelope on a personal computer. Variations can include, for example, arrangements in which corrections for nonlinearity of the detector in the field sensor, or for the frequency response of the field sensor, are carried out in the field processor instead of in the personal computer, arrangements in which the clock bits are generated in the sensor and transmitted to the field processor independently of the field data, and arrangements in which the clock data are transmitted by encoding the data stream. Accordingly, these and numerous other modifications of the apparatus described can be made without departing from the scope of the invention, which is defined in the following claims.

What is claimed is:

1. Apparatus for displaying the modulation envelope of an amplitude-modulated RF electric field comprising:
a field sensor for receiving said RF electric field and for generating an output in the form of digital samples representing the amplitude of said field;
a field processor connected to the field sensor for receiving said output of the field sensor and generating a web page for display on a personal computer, the web page including a plot showing changes in the amplitude of said envelope over an interval of time; and
a personal computer connected to said field processor;
in which:
said field sensor comprises an antenna, a detector having an input connected to the antenna and providing an output, and a sampling circuit responsive to the detector and providing, in digital format, sequential samples representing the amplitude of an amplitude-modulated RF electric field received by the antenna;
said field processor comprises a receiver for receiving said sequential samples, a microcontroller responsive to the receiver, the microcontroller including a buffer memory for holding said samples, trigger-responsive means for uploading data packets from the buffer memory to said web page, and a bit alignment correction circuit, responsive to the buffer memory, for detecting and correcting misalignment of the data bits in said buffer memory; and
said personal computer is a personal computer arranged to receive said data packets, and to display said data packets as an oscilloscope display of the modulation envelope of the RF electric field on a web page.

2. The apparatus according to claim 1, wherein each of said sequential samples includes at least one data bit always set to zero, and in which said bit alignment correction circuit calculates bit misalignment by detecting said at least one data bit.

3. The apparatus according to claim 1, wherein each of said sequential samples includes at least one data bit always set to zero, and in which said bit alignment correction circuit calculates bit misalignment by detecting said at least one data bit, and corrects for said bit misalignment by turning off a clock used to control data transfer by a number of bits corresponding to the detected misalignment.

4. The apparatus according to claim 1, wherein each of said sequential samples includes leading and trailing data bits, always set to zero, and in which said bit alignment correction circuit calculates bit misalignment by detecting said leading and trailing data bits.

5. The apparatus according to claim 1, wherein each of said sequential samples includes leading and trailing data bits, always set to zero, and in which said bit alignment correction circuit calculates bit misalignment by detecting said leading and trailing data bits, and corrects for said bit misalignment by turning off a clock used to control data transfer by a number of bits corresponding to the detected misalignment.

6. The apparatus according to claim 1, wherein each of said sequential samples includes at least two leading data bits and at least two trailing data bits, said leading and trailing data bits being always set to zero, and in which said bit alignment correction circuit calculates bit misalignment by detecting said leading and trailing data bits.

7. The apparatus according to claim 1, wherein each of said sequential samples includes at least two leading data bits and at least two trailing data bits, said leading and trailing data bits being always set to zero, and in which said bit alignment correction circuit calculates bit misalignment by detecting said leading and trailing data bits, and corrects for said bit misalignment by turning off a clock used to control data transfer by a number of bits corresponding to the detected misalignment.

8. The apparatus according to claim 1, wherein said sampling circuit provides said samples in the form a stream of data bits, and wherein said field processor includes a clock recovery unit for deriving a synchronization clock signal from said stream of data bits, and said bit alignment correction circuit is responsive to said buffer memory, and to said synchronization clock signal, for detecting and correcting misalignment of the data bits in said buffer memory.

9. Apparatus for displaying the modulation envelope of an amplitude-modulated RF electric field comprising:
a field sensor for receiving said RF electric field and providing an output in the form of digital samples representing the amplitude of said RF electric field;
a field processor connected to the receive said output of said field sensor for generating a web page for display on a personal computer, the web page including a plot showing changes in the amplitude of said envelope over an interval of time, said field processor including a memory storing data characterizing said nonlinearity of the field sensor; and
a personal computer connected to the field processor to retrieve and display said web page;
said field sensor comprising a detector providing an output representing the amplitude of said RF electric field, and a sampling circuit, responsive to the output of said detector and providing said digital samples as sequential samples representing the amplitude of RF electric field; and
said field processor comprising a receiver for receiving said sequential samples, and a microcontroller responsive to said receiver, the microcontroller including a buffer memory for holding said samples, and trigger-responsive means for uploading data packets from said buffer memory to a web page displayed on said personal computer;
said personal computer including means for retrieving said data packets, and displaying said data packets as an oscilloscope display of the modulation envelope of said RF electric field on said web page; and
said field processor including a bit alignment correction circuit, responsive to said buffer memory for detecting and correcting misalignment of data bits in said buffer memory.

10. Apparatus for displaying the modulation envelope of an amplitude-modulated RF electric field comprising:
a field sensor for receiving said RF electric field and providing an output in the form of digital samples representing the amplitude of said RF electric field;
a field processor connected to receive said output of said field sensor for generating a web page for display on a personal computer, the web page including a plot showing changes in the amplitude of said envelope over an interval of time, said field processor including a memory storing data characterizing said nonlinearity of the field sensor; and
a personal computer connected to the field processor to retrieve and display said web page;
said field sensor comprising a detector providing an output representing the amplitude of said RF electric field, and a sampling circuit, responsive to the output of said detector and providing said digital samples as sequential samples representing the amplitude of said RF electric field; and
said field processor comprising a receiver for receiving said sequential samples, and a microcontroller responsive to said receiver, the microcontroller including a buffer memory for holding said samples, and trigger-responsive means for uploading data packets from said buffer memory to a web page displayed on said personal computer;
said personal computer including means for retrieving said data packets, and displaying said data packets as an oscilloscope display of the modulation envelope of said RF electric field on said web page; and
in which:
said sampling circuit comprises a clock pulse generator and an analog-to-digital converter, responsive to clock pulses from the clock pulse generator and to the output of said detector, for producing a serial stream of data bits in sequential groups, each group of data bits representing a sample of the amplitude of said amplitude-modulated RF electric field;
said field sensor also includes an electrical-to-optical converter connected to receive an electrical output from said analog-to-digital converter and to produce a modulated optical signal for transmitting, in the form of a beam of light, data corresponding to the data represented by said serial stream of data bits produced by said analog-to-digital converter, and a fiber-optic cable connected to the electrical-to-optical converter for receiving and carrying said beam of light to said field processor;
the receiver of said field processor is an optical receiver, connected to said fiber-optic cable, for receiving said beam of light and generating an electrical signal in the form of a stream of data bits corresponding to the serial stream of data bits produced by said analog-to-digital converter;
said field processor includes a clock recovery unit for deriving a synchronization clock signal from the stream of data bits, and a bit alignment correction circuit, responsive to said buffer memory and to said synchronization clock signal, for detecting and correcting misalignment of the data bits in said buffer memory.
